(19) United States
(12) Patent Application Publication
(10) Pub. No.: US 2025/0056883 A1
(43) Pub. Date: Feb. 13, 2025

(54) DISPLAY DEVICE AND METHOD FOR MANUFACTURING SAME

(71) Applicant: Sharp Display Technolology Corporation, Kameyama City, Mie (JP)

(72) Inventors: Tadayoshi MIYAMOTO, Kameyama City, Mie (JP); Sohtaroh TANAKA, Kameyama City, Mie (JP); Fumie YASHIRO, Kameyama City, Mie (JP)

(21) Appl. No.: 18/726,428

(22) PCT Filed: Mar. 16, 2022
(86) PCT No.: PCT/JP2022/012037

§ 371 Date: Jul. 3, 2024

(51) Int. Cl. H01L 27/12; H10K 59/12; H10K 59/121; H10K 102/00

(52) U.S. Cl. CPC H01L 27/1251; H01L 27/1218; H01L 27/124; H10K 59/1201; H10K 59/1213; H10K 2102/311

(57) ABSTRACT

Each of terminal electrodes including first and second terminal electrodes of a first thin-film transistor, and third and fourth terminal electrodes of a second thin-film transistor is provided with a lower metal layer, a middle metal layer, and an upper metal layer stacked sequentially. The middle metal layer has a lower electrical resistance and a lower melting point than the lower metal layer and the upper metal layer. At an end of each of the terminal electrodes, the end face of the lower metal layer and the end face of the middle metal layer are flush with each other, and the upper metal layer is provided so as to cover the end faces flush with each other.

### TECHNICAL FIELD

The disclosure relates to a display device and a method for manufacturing the same.

### BACKGROUND ART

Attention has been recently drawn to self-emission organic EL display devices incorporating organic electroluminescence (hereinafter, also referred to as EL) elements, as display devices alternative to liquid crystal displays. Such an organic EL display device has a plurality of thin-film transistors (hereinafter, also referred to as “TFTs”) provided for each subpixel, which is the minimum unit of an image. Here, well-known examples of a semiconductor layer constituting TFTs include, but not limited to, a semiconductor layer made of high-mobility polysilicon, and a semiconductor layer made of an oxide semiconductor with a small leakage current, such as an In—Ga—Zn—O semiconductor.

For instance, Patent Literature 1 discloses a display device having a hybrid structure in which a first TFT composed of a polysilicon semiconductor, and a second TFT composed of an oxide semiconductor are individually formed on a substrate.

### CITATION LIST

### Patent Literature

Patent Literature 1: Japanese Unexamined Patent Application Publication No. 2020-17558

### SUMMARY

### Technical Field

By the way, such a hybrid-structured organic EL display device in which a polysilicon TFT and an oxide semiconductor TFT are provided for each subpixel has an overlap between a lower wire made of the same material and formed in the same layer as the gate electrode of the polysilicon TFT, and an upper wire made of the same material and formed in the same layer as the gate electrode of the oxide semiconductor TFT, in order to enhance the aperture ratio of each subpixel. Here, the overlap between the lower and upper wires produces a large surface step height in a stack of an inorganic insulating film covering the lower wire and another inorganic insulating film covering the upper wire; hence, forming conductive layers, such as a plurality of wires, onto this stacked film causes a metal film (see R in FIG. 20), constituting the conductive layers, to remain at the surface step height of the stacked film, so that the conductive layers adjacent to each other can be short-circuited by the remaining metal film.

The disclosure has been made in view of this problem and aims to prevent a short circuit between conductive layers adjacent to each other.

### Solution to Problem

To achieve the above object, a display device according to the disclosure includes the following: a base substrate; and a thin-film transistor layer provided on the base substrate, and in which a first semiconductor film composed of polysilicon, a first inorganic insulating film, a first metal film, a second inorganic insulating film, a second semiconductor film composed an oxide semiconductor, a third inorganic insulating film as well as a second metal film, and a fourth inorganic insulating film as well as a third metal film are stacked sequentially. The thin-film transistor layer includes a first thin-film transistor and a second thin-film transistor provided for each of subpixels constituting a display region, wherein the first thin-film transistor has a first semiconductor layer composed of the first semiconductor film, and the second thin-film transistor has a second semiconductor layer composed of the second semiconductor film. The first thin-film transistor includes the following: the first semiconductor layer having a first conductor region and a second conductor region defined so as to be spaced from each other, and having a first channel region defined between the first conductor region and the second conductor region; a first gate electrode composed of the first metal film, and provided on the first semiconductor layer with the first inorganic insulating film interposed between the first gate electrode and the first semiconductor layer; and a first terminal electrode and a second terminal electrode composed the third metal film, provided so as to be spaced from each other, and electrically connected to the first conductor region and the second conductor region, respectively. The second thin-film transistor includes the following: the second semiconductor layer having a third conductor region and a fourth conductor region defined so as to be spaced from each other, and having a second channel region defined between the third conductor region and the fourth conductor region; a second gate electrode composed of the second metal film, and provided on the second semiconductor layer with the third inorganic insulating film interposed between the second gate electrode and the second semiconductor layer; and a third terminal electrode and a fourth terminal electrode composed of the third metal film, provided so as to be spaced from each other, and electrically connected to the third conductor region and the fourth conductor region, respectively. Each of the first terminal electrode, the second terminal electrode, the third terminal electrode, and the fourth terminal electrode includes a lower metal layer, a middle metal layer, and an upper metal layer stacked sequentially. The middle metal layer has a lower electrical resistance and a lower melting point than the lower metal layer and the upper metal layer. At an end of each of the first terminal electrode, the second terminal electrode, the third terminal electrode, and the fourth terminal electrode, the end face of the lower metal layer and the end face of the middle metal layer are flush with each other, and the upper metal layer is provided so as to cover the end faces flush with each other.

### Advantageous Effect of Disclosure

The disclosure can prevent a short circuit between conductive layers adjacent to each other.

### BRIEF DESCRIPTION OF DRAWINGS

FIG. 1 is a plan view of a schematic configuration of an organic EL display device according to a first embodiment of the disclosure.

FIG. 2 is a plan view of a display region of the organic EL display device according to the first embodiment of the disclosure.

FIG. 3 is a sectional view of the display region of the organic EL display device according to the first embodiment of the disclosure.

FIG. 4 is an equivalent circuit diagram of a TFT layer, which constitutes the organic EL display device according to the first embodiment of the disclosure.

FIG. 5 is a sectional view of a terminal electrode, which constitutes the organic EL display device according to the first embodiment of the disclosure.

FIG. 6 is a sectional view of an organic EL layer, which constitutes the organic EL display device according to the first embodiment of the disclosure.

FIG. 7 illustrates a process step for manufacturing the organic EL display device according to the first embodiment of the disclosure and is a first sectional view.

FIG. 8 illustrates a process step for manufacturing the organic EL display device according to the first embodiment of the disclosure and is a second sectional view subsequent to the view in FIG. 7.

FIG. 9 illustrates a process step for manufacturing the organic EL display device according to the first embodiment of the disclosure and is a third sectional view subsequent to the view in FIG. 8.

FIG. 10 illustrates a process step for manufacturing the organic EL display device according to the first embodiment of the disclosure and is a fourth sectional view subsequent to the view in FIG. 9.

FIG. 11 illustrates a process step for manufacturing the organic EL display device according to the first embodiment of the disclosure and is a fifth sectional view subsequent to the view in FIG. 10.

FIG. 12 illustrates a process step for manufacturing the organic EL display device according to the first embodiment of the disclosure and is a sixth sectional view subsequent to the view in FIG. 11.

FIG. 13 illustrates a process step for manufacturing the organic EL display device according to the first embodiment of the disclosure and is a seventh sectional view subsequent to the view in FIG. 12.

FIG. 14 illustrates a process step for manufacturing the organic EL display device according to the first embodiment of the disclosure and is an eighth sectional view subsequent to the view in FIG. 13.

FIG. 15 illustrates a process step for manufacturing the organic EL display device according to the first embodiment of the disclosure and is a ninth sectional view subsequent to the view in FIG. 14.

FIG. 16 illustrates a process step for manufacturing the organic EL display device according to the first embodiment of the disclosure and is a tenth sectional view subsequent to the view in FIG. 15.

FIG. 17 illustrates a process step for manufacturing the organic EL display device according to the first embodiment of the disclosure and is an eleventh sectional view subsequent to the view in FIG. 16.

FIG. 18 illustrates a process step for manufacturing the organic EL display device according to the first embodiment of the disclosure and is a twelfth sectional view subsequent to the view in FIG. 17.

FIG. 19 illustrates a process step for manufacturing the organic EL display device according to the first embodiment of the disclosure and is a thirteenth sectional view subsequent to the view in FIG. 18.

FIG. 20 illustrates a process step for manufacturing the organic EL display device according to the first embodiment of the disclosure and is a sectional view taken along line XX-XX in FIG. 2 after a step of patterning a third metal film.

### DESCRIPTION OF EMBODIMENTS

The embodiment of the disclosure will be detailed on the basis of the drawings. It is noted that the disclosure is not limited to the following embodiment.

### First Embodiment

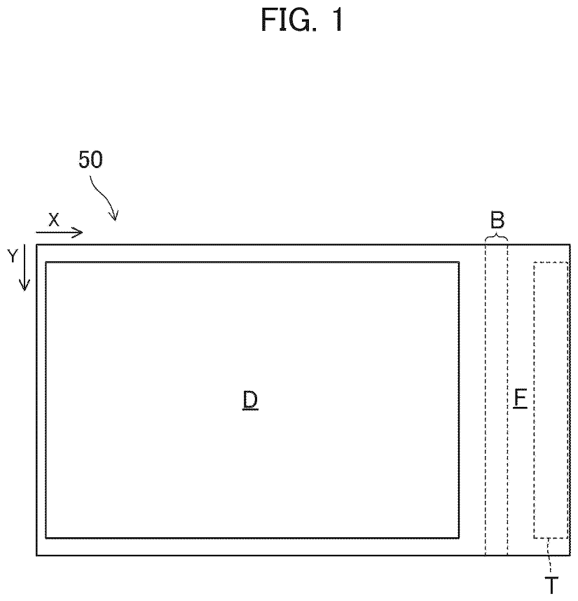

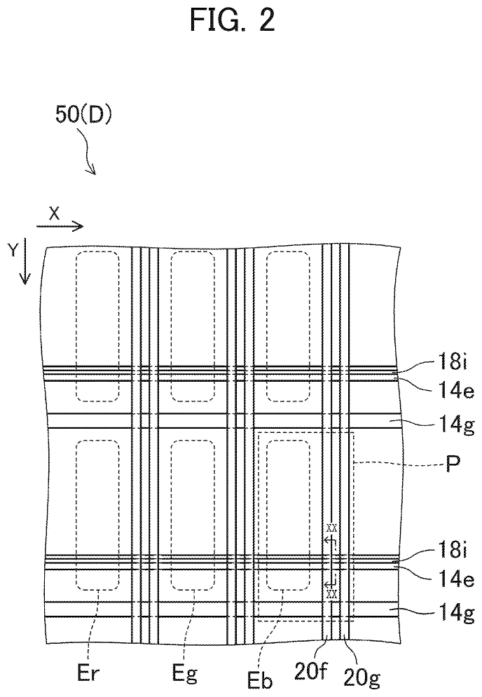

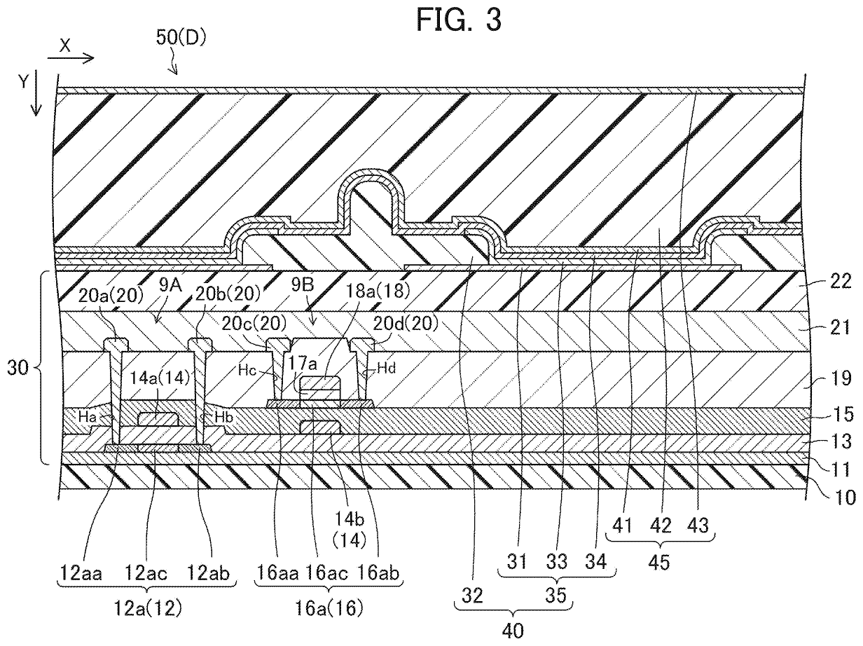

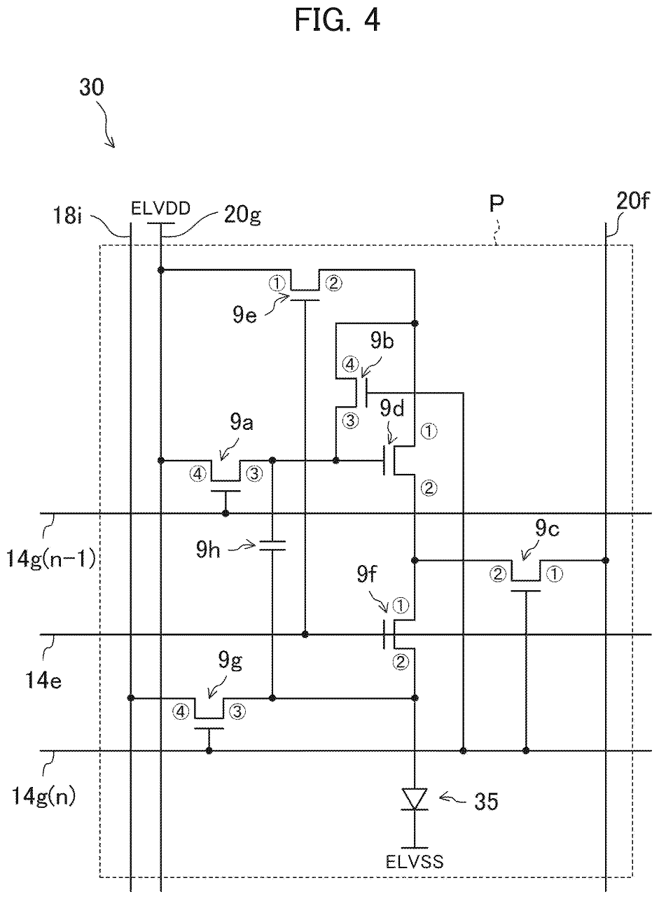

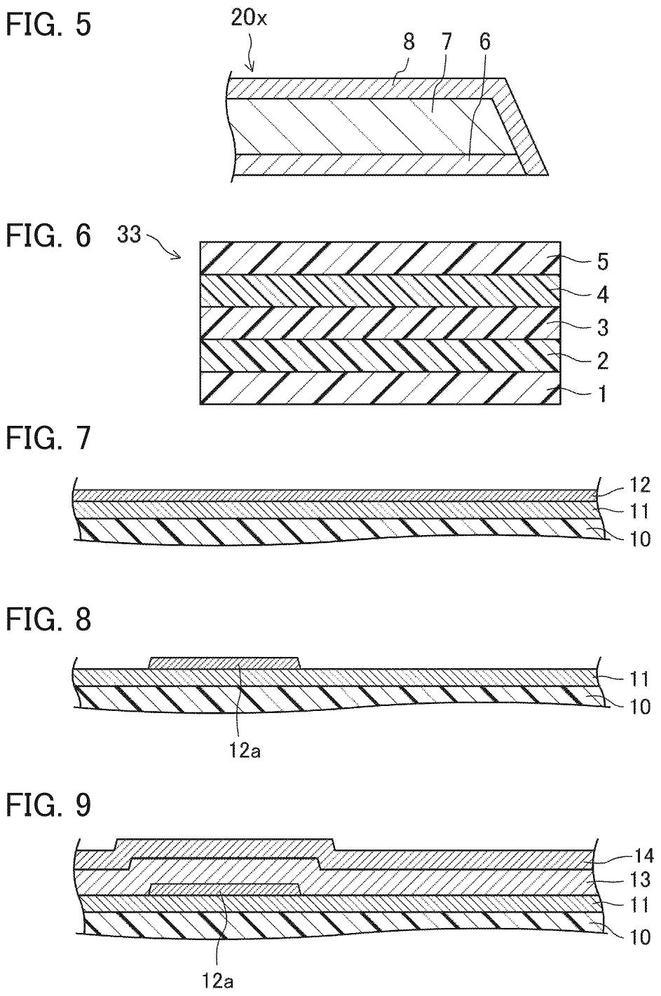

FIG. 1 to FIG. 20 illustrate a display device according to a first embodiment of the disclosure, and a method for manufacturing the same. It is noted that the following embodiment will describe an organic EL display device provided with an organic EL element layer by way of example, as a display device provided with a light-emitting element layer. Here, FIG. 1 is a plan view of a schematic configuration of an organic EL display device 50 according to this embodiment. In addition, FIG. 2 and FIG. 3 are a plan view and a sectional view of a display region D of the organic EL display device 50. In addition, FIG. 4 is an equivalent circuit diagram of a TFT layer 30, which constitutes the organic EL display device 50. In addition, FIG. 5 is a sectional view of a terminal electrode 20x, which constitute the organic EL display device 50. In addition, FIG. 6 is a sectional view of an organic EL layer 33, which constitutes the organic EL display device 50.

As illustrated in FIG. 1, the organic EL display device 50 has, for instance, the display region D shaped in a rectangle and provided for image display, and a frame region F provided around the display region D. It is noted that although this embodiment describes the rectangular display region D by way of example, this rectangular shape includes substantially rectangular shapes, such as a shape with an arc-shaped side, a shape with an arc-shaped corner, and a shape with part of a side being cut.

The display region D includes a plurality of subpixels P arranged in matrix, as illustrated in FIG. 2. Further, for instance, a subpixel P having a red emission region Er for red display, a subpixel P having a green emission region Eg for green display, and a subpixel P having a blue emission region Eb for blue display are provided in the display region D so as to be adjacent to one another, as illustrated in FIG. 2. It is noted that the display region D is structured such that for instance, three adjacent subpixels P having the red emission region Er, green emission region Eg, and blue emission region Eb constitute a single pixel.

The frame region F includes a terminal section T provided at the end in the positive X-direction in FIG. 1 so as to extend in one direction (the Y-direction in FIG. 1). The frame region F also includes, as illustrated in FIG. 1, a bending section B provided between the display region D and the terminal section T so as to extend in one direction (the Y-direction of the drawing); here, the bending section B is, for instance, 180° (U-shape) bendable about a bending axis, which is in the Y-direction of the drawing.

The organic EL display device 50 includes the following as illustrated in FIG. 3: a resin substrate 10 provided as a base substrate; the TFT layer 30 provided on the resin substrate 10; an organic EL element layer 40 provided as a light-emitting element layer on the TFT layer 30; and a sealing film 45 provided on the organic EL element layer 40.

The resin substrate 10 is composed of an organic resin material, such as polyimide resin.

The TFT layer 30 includes the following as illustrated in FIG. 3: the base coat film 11 provided on the resin substrate 10; four first TFTs 9A, three second TFTs 9B, and one capacitor 9h (see FIG. 4) provided on the base coat film 11 for each subpixel P; and a protective insulating film 21 and a flattening film 22 provided sequentially on the first TFTs 9A, second TFTs 9B, and capacitors 9h. Here, the TFT layer 30 includes, as illustrated in FIG. 2, a plurality of gate lines 14g provided so as to extend in parallel with each other in the X-direction of the drawing. The TFT layer 30 also includes, as illustrated in FIG. 2, a plurality of emission control lines 14e provided so as to extend in parallel with each other in the X-direction of the drawing. The TFT layer 30 also includes, as illustrated in FIG. 2, a plurality of second initialization power-supply lines 18i provided so as to extend in parallel with each other in the X-direction of the drawing. It is noted that each emission control line 14e is provided so as to be adjacent to a corresponding one of the gate lines 14g and a corresponding one of the second initialization power-supply lines 18i, as illustrated in FIG. 2. It is also noted that each second initialization power-supply line 18i is provided so as to overlap a corresponding one of the emission control lines 14e, as illustrated in FIG. 2. The TFT layer 30 also includes, as illustrated in FIG. 2, a plurality of source lines 20f provided so as to extend in parallel with each other in the Y-direction of the drawing. The TFT layer 30 also includes, as illustrated in FIG. 2, a plurality of power supply lines 20g provided so as to extend in parallel with each other in the Y-direction of the drawing. It is noted that each power supply line 20g is provided so as to be adjacent to a corresponding one of the source lines 20f, as illustrated in FIG. 2.

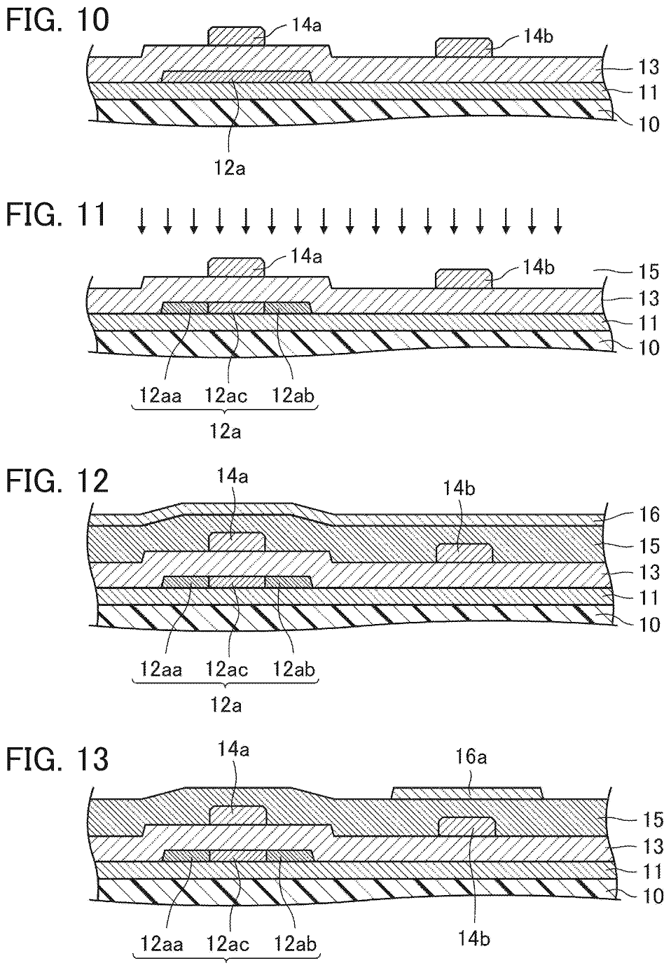

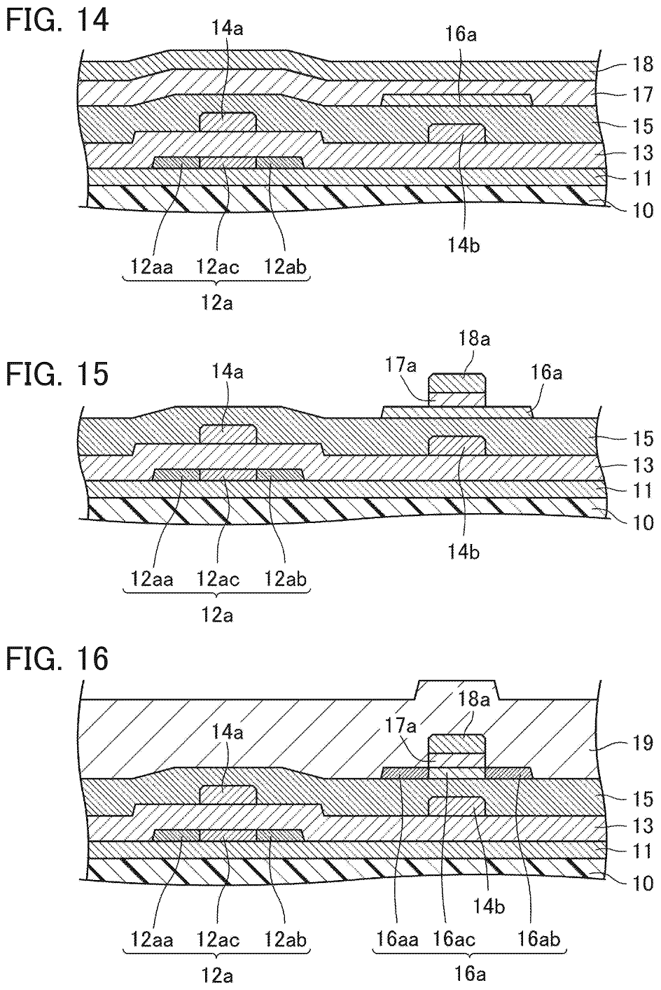

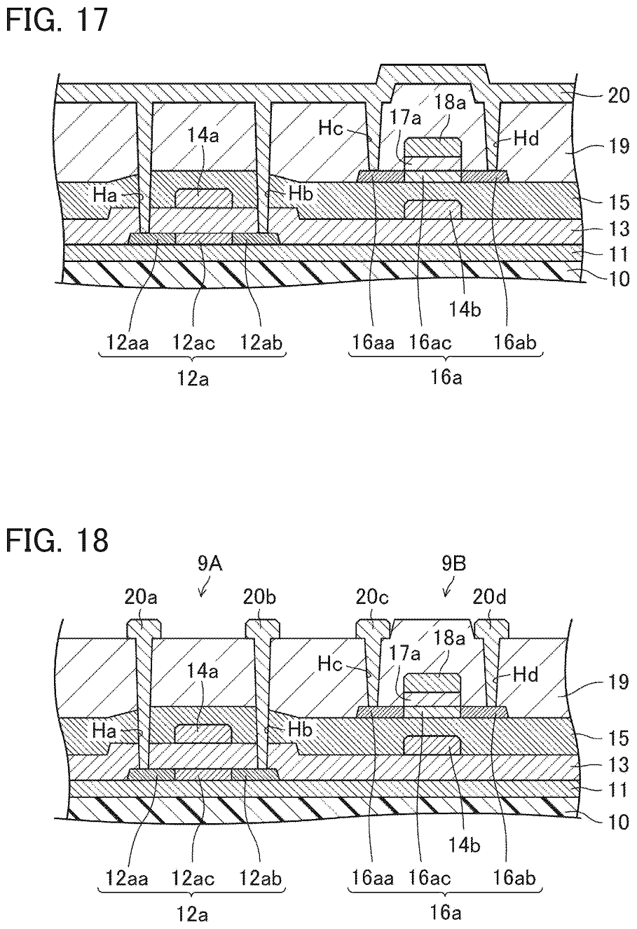

The TFT layer 30 is structured, as illustrated in FIG. 3, such that the base coat film 11, a first semiconductor film 12 (see FIG. 7) as well as a first gate insulating film (first inorganic insulating film) 13, both of which will be described later on, a first metal film 14 (see FIG. 9) as well as a first interlayer insulating film (second inorganic insulating film) 15, both of which will be described later on, a second semiconductor film 16 (see FIG. 12) as well as a second gate insulating film (third inorganic insulating film) 17a, both of which will be described later on, a second metal film 18 (see FIG. 14) as well as a second interlayer insulating film (fourth inorganic insulating film) 19, both of which will be described later on, a third metal film 20 (see FIG. 17), which will be described later on, the protective insulating film 21, and the flattening film 22 are stacked sequentially on the resin substrate 10. Here, the gate lines 14g and the emission control lines 14e are composed of the first metal film 14. In addition, the second initialization power-supply lines 18i are composed of the second metal film 18. In addition, the source lines 20f and the power supply lines 20g are composed of the third metal film 20.

The base coat film 11, the first gate insulating film 13, the first interlayer insulating film 15, the second gate insulating film 17a, the second interlayer insulating film 19, and the protective insulating film 21 are composed of, for instance, an inorganic insulating monolayer film or inorganic insulating multilayer film, such as a silicon nitride film, a silicon oxide film, or a silicon oxide nitride film. Here, at least the first interlayer insulating film 15 adjacent to a second semiconductor layer 16a, which will be described later on, and the second gate insulating film 17a adjacent to the second semiconductor layer 16a are composed of a silicon oxide film.

The first TFTs 9A each include the following as illustrated in FIG. 3: a first semiconductor layer 12a provided on the base coat film 11; a first gate electrode 14a provided on the first semiconductor layer 12a with the first gate insulating film 13 interposed therebetween; and a first terminal electrode 20a and a second terminal electrode 20b provided on the second interlayer insulating film 19 so as to be spaced from each other.

The first semiconductor layer 12a is composed of the first semiconductor layer 12, which is made of polysilicon, such as low-temperature polysilicon (LTPS), and this layer includes the following as illustrated in FIG. 3: a first conductor region 12aa and a second conductor region 12ab defined so as to be spaced from each other; and a first channel region 12ac defined between the first conductor region 12aa and the second conductor region 12ab.

The first gate electrode 14a is composed of the first metal film 14, is provided so as to overlap the first channel region 12ac of the first semiconductor layer 12a, as illustrated in FIG. 3, and is configured to control the electrical continuity between the first conductor region 12aa and second conductor region 12ab of the first semiconductor layer 12a.

The first terminal electrode 20a and the second terminal electrode 20b are composed of the third metal film 20 and are, as illustrated in FIG. 3, electrically connected to the first conductor region 12aa and second conductor region 12ab of the first semiconductor layer 12a, respectively, via a first contact hole Ha and a second contact hole Hb both formed in a stack of the first gate insulating film 13, first interlayer insulating film 15, and second interlayer insulating film 19.

The second TFTs 9B each include the following as illustrated in FIG. 3: the second semiconductor layer 16a provided on the first interlayer insulating film 15; a second gate electrode 18a provided on the second semiconductor layer 16a with the second gate insulating film 17a interposed therebetween; a third gate electrode 14b provided closer to the resin substrate 10 than the second semiconductor layer 16a with the first interlayer insulating film 15 interposed therebetween; and a third terminal electrode 20c and a fourth terminal electrode 20d provided on the second interlayer insulating film 19 so as to be spaced from each other.

The second semiconductor layer 16a is composed of the second semiconductor film 16, which is made of an In—Ga—Zn—O oxide semiconductor for instance, and this layer has the following as illustrated in FIG. 3: a third conductor region 16aa and a fourth conductor region 16ab defined so as to be spaced from each other; and a second channel region 16ac defined between the third conductor region 16aa and the fourth conductor region 16ab. Here, the In—Ga—Zn—O semiconductor is a ternary oxide of indium (In), gallium (Ga), and zinc (Zn) and may contain In, Ga, and Zn at any ratio (composition ratio). Further, the In—Ga—Zn—O semiconductor may be amorphous or crystalline. It is noted that a preferable crystalline In—Ga—Zn—O semiconductor is a crystalline In—Ga—Zn—O semiconductor whose c-axis is nearly perpendicular to a layer surface. It is also noted that other kinds of oxide semiconductor may be contained instead of an In—Ga—Zn—O semiconductor. The other kinds of oxide semiconductor may include an In—Sn—Zn—O semiconductor (e.g., In₂O₃—SnO₂—ZnO, InSnZnO) for instance. Here, the In—Sn-Zn—O semiconductor is a ternary oxide of indium (In), tin (Sn), and zinc (Zn). Further, the other kinds of oxide semiconductor may include, but not limited to, an In—Al—Zn—O semiconductor, an In—Al—Sn—Zn—O semiconductor, a Zn—O semiconductor, an In—Zn—O semiconductor, a Zn—Ti—O semiconductor, a Cd—Ge—O semiconductor, a Cd—Pb—O semiconductor, a cadmium oxide (CdO), a Mg—Zn—O semiconductor, an In—Ga—Sn—O semiconductor, an In—Ga-O semiconductor, a Zr—In-Zn—O semiconductor, a Hf—In—Zn—O semiconductor, an Al—Ga—Zn—O semiconductor, a Ga—Zn—O semiconductor, an In—Ga—Zn—Sn—O semiconductor, InGaO₃ (ZnO)₅, a magnesium zinc oxide (MgₓZn₁₋ₓO), and a cadmium zinc oxide (CdₓZn₁₋ₓO). It is noted that a usable Zn—O semiconductor is an amorphous semiconductor of ZnO with one or more kinds of impurity elements selected from among, but not limited to, a Group I element, a Group XIII element, a Group XIV element, a Group XV element, and a Group XVII element being added thereto, a polycrystalline semiconductor of such ZnO, or a crystallite semiconductor of such ZnO containing amorphous and polycrystalline substances; alternatively, a usable Zn—O semiconductor is a ZnO semiconductor without any impurity elements being added thereto.

The second gate electrode 18a is composed of the second metal film 18, is provided so as to overlap the second channel region 16ac of the second semiconductor layer 16a, as illustrated in FIG. 3, and is configured to control the electrical continuity between the third conductor region 16aa and fourth conductor region 16ab of the second semiconductor layer 16a. Here, the second gate insulating film 17a is provided in the form of an island so as to overlap the second gate electrode 18a, as illustrated in FIG. 3.

The third gate electrode 14b is composed of the first metal film 14, is provided so as to overlap the second channel region 16ac of the second semiconductor layer 16a, as illustrated in FIG. 3, and is configured to be electrically connected to the second gate electrode 18a to thus control the electrical continuity between the third conductor region 16aa and fourth conductor region 16ab of the second semiconductor layer 16a. In addition, the third gate electrode 14b, which overlaps the second channel region 16ac of the second semiconductor layer 16a, is configured to prevent light from entering the second channel region 16ac, or prevent impurity ions contained in the resin substrate 10 from reaching the second channel region 16ac.

The third terminal electrode 20c and the fourth terminal electrode 20d are composed of the third metal film 20 and are, as illustrated in FIG. 3, electrically connected to the third conductor region 16aa and fourth conductor region 16ab of the second semiconductor layer 16a, respectively, via a third contact hole He and a fourth contact hole Hd both formed in the second interlayer insulating film 19.

Each of the terminal electrodes 20x, that is, each of the first terminal electrode 20a, second terminal electrode 20b, third terminal electrode 20c and fourth terminal electrode 20d includes a lower metal layer 6, a middle metal layer 7, and an upper metal layer 8 stacked sequentially, as illustrated in FIG. 5. Here, the lower metal layer 6 and the upper metal layer 8 are composed of a titanium film, a molybdenum film or other films for instance. In addition, the middle metal layer 7 is composed of an aluminum film or other films for instance. The middle metal layer 7 thus has a lower electrical resistance and a lower melting point than the lower metal layer 6 and the upper metal layer 8. It is noted that the lower metal layer 6 and the upper metal layer 8 may be composed of a titanium alloy film or a molybdenum alloy film for instance, and that the middle metal layer 7 may be composed of an aluminum alloy film for instance. Moreover, at an end of each terminal electrode 20x, the end face of the lower metal layer 6 and the end face of the middle metal layer 7 are flush with each other, and the upper metal layer 8 is provided so as to cover these flush end faces. It is noted that the source lines 20f and the power supply lines 20g, which are made of the same material and formed in the same layer as the first terminal electrode 20a, second terminal electrode 20b, third terminal electrode 20c and fourth terminal electrode 20d, each include the lower metal layer 6, the middle metal layer 7, and the upper metal layer 8 stacked sequentially, like each terminal electrode 20x. Moreover, at the ends on both sides of the source line 20f and power supply line 20g, the end face of the lower metal layer 6 and the end face of the middle metal layer 7 are flush with each other, and the upper metal layer 8 is provided so as to cover these flush end faces (see FIG. 5).

This embodiment describes a write TFT 9c, a driving TFT 9d, a power supply TFT 9e, and an emission control TFT 9f, all of which will be described later on (see FIG. 4), by way of example as the four first TFTs 9A having the first semiconductor layer 12a composed of polysilicon and describes an initialization TFT 9a, a compensation TFT 9b, and an anode discharge TFT 9g, all of which will be described later on (see FIG. 4), by way of example as the three second TFTs 9B having the second semiconductor layer 16a composed of an oxide semiconductor. It is noted that in the equivalent circuit diagram in FIG. 4, the first terminal electrodes 20a and second terminal electrodes 20b of the respective TFTs 9c, 9d, 9e, and 9f are denoted by circled numerals 1 and 2, and the third terminal electrodes 20c and fourth terminal electrodes 20d of the respective TFTs 9a, 9b, and 9g are denoted by circled numerals 3 and 4. It is also noted that the equivalent circuit diagram in FIG. 4 includes a part of the pixel circuit of the subpixel P in the (n−1)th row and mth column, as well as the pixel circuit of the subpixel P in the nth row and mth column. It is also noted that although the power supply line 20g, via which a high power-supply voltage ELVDD is supplied, serves also as a first initialization power-supply line in the equivalent circuit diagram in FIG. 4, the power supply line 20g and the first initialization power-supply line may be provided separately. It is also noted that although the second initialization power-supply line 18i receives the same voltage as a low power-supply voltage ELVSS, it may receive a voltage that is different from the low power-supply voltage ELVSS, and at which an organic EL element 35, which will be described later on, is turned off.

As illustrated in FIG. 4, the initialization TFT 9a is configured in each subpixel P such that its gate electrode is electrically connected to the gate line 14g(n−1) at the anterior stage (n−1 stage), such that its third terminal electrode is electrically connected to a lower conductive layer of the capacitor 9h, which will be described later on, and to the gate electrode of the driving TFT 9d, and such that its fourth terminal electrode is electrically connected to the power supply line 20g.

As illustrated in FIG. 4, the compensation TFT 9b is configured in each subpixel P such that its gate electrode is electrically connected to the gate line 14g(n) at the target stage (nth stage), such that its third terminal electrode is electrically connected to the gate electrode of the driving TFT 9d, and such that its fourth terminal electrode is electrically connected to the first terminal electrode of the driving TFT 9d.

As illustrated in FIG. 4, the write TFT 9c is configured in each subpixel P such that its gate electrode is electrically connected to the gate line 14g(n) at the target stage (nth stage), such that its first terminal electrode is electrically connected to the corresponding source line 20f, and such that its second terminal electrode is electrically connected to the second terminal electrode of the driving TFT 9d.

As illustrated in FIG. 4, the driving TFT 9d is configured in each subpixel P such that its gate electrode is electrically connected to the third terminal electrodes of the respective initialization TFT 9a and compensation TFT 9b, such that its first terminal electrode is electrically connected to the fourth terminal electrode of the compensation TFT 9b, and the second terminal electrode of the power supply TFT 9e, and such that its second terminal electrode is electrically connected to the second terminal electrode of the write TFT 9c, and the first terminal electrode of the emission control TFT 9f. Here, the driving TFT 9d is configured to control a driving current for the organic EL element 35.

As illustrated in FIG. 4, the power supply TFT 9e is configured in each subpixel P such that its gate electrode is electrically connected to the emission control line 14e at the target stage (nth stage), such that its first terminal electrode is electrically connected to the power supply line 20g, and such that its second terminal electrode is electrically connected to the first terminal electrode of the driving TFT 9d.

As illustrated in FIG. 4, the emission control TFT 9f is configured in each subpixel P such that its gate electrode is electrically connected to the emission control line 14e at the target stage (nth stage), such that its first terminal electrode is electrically connected to the second terminal electrode of the driving TFT 9d, and such that its second terminal electrode is electrically connected to a first electrode 31, which will be described later on, of the organic EL element 35, which will be described later on.

As illustrated in FIG. 4, the anode discharge TFT 9g is configured in each subpixel P such that its gate electrode is electrically connected to the gate line 14g(n) at the target stage (nth stage), such that its third terminal electrode is electrically connected to the first electrode 31 of the organic EL element 35, and such that its fourth terminal electrode is electrically connected to the second initialization power-supply line 18i.

The capacitor 9h includes the following for example: a lower conductive layer (not shown) composed of the first metal film 14; the first interlayer insulating film 15 and a second gate insulating film (not shown) provided so as to cover the lower conductive layer; and an upper conductive layer (not shown) provided on the second gate insulating film so as to overlap the lower conductive layer, and composed of the second metal film 18. As illustrated in FIG. 4, the capacitor 9h is also configured in each subpixel P such that its lower conductive layer is electrically connected to the gate electrode 14b of the driving TFT 9d, and the third terminal electrodes of the respective initialization TFT 9a and compensation TFT 9b, and such that its upper conductive layer is electrically connected to the third terminal electrode of the anode discharge TFT 9g, the second terminal electrode of the emission control TFT 9f, and the first electrode 31 of the organic EL element 35.

The flattening film 22 has a flat surface in the display region D and is composed of, but not limited to, an organic resin material, such as polyimide resin or acrylic resin, or a polysiloxane spin-on-glass (SOG) material.

The organic EL element layer 40 includes the following as illustrated in FIG. 3: a plurality of organic EL elements 35 provided as a plurality of light-emitting elements so as to be arranged in matrix in correspondence with a plurality of subpixels P; and an edge cover 32 provided in the form of a lattice shared among all the subpixels P so as to cover the perimeters of the first electrodes 31 of the individual organic EL elements 35.

The organic EL element 35 in each subpixel P includes the following as illustrated in FIG. 3: the first electrode 31 provided on the flattening film 22 of the TFT layer 30; the organic EL layer 33 provided on the first electrode 31; and a second electrode 34 provided on the organic EL layer 33.

The first electrode 31 is electrically connected to the second terminal electrode of the emission control TFT 9f in each subpixel P via a contact hole formed in a stack of the protective insulating film 21 and flattening film 22. Further, the first electrode 31 has the function of injecting holes (positive holes) into the organic EL layer 33. Further, the first electrode 31 is more desirably made of a material having a small work function, in order to improve the efficiency of hole injection into the organic EL layer 33. Here, the first electrode 31 is made of metal for instance, including silver (Ag), aluminum (Al), vanadium (V), cobalt (Co), nickel (Ni), tungsten (W), gold (Au), titanium (Ti), ruthenium (Ru), manganese (Mn), indium (In), ytterbium (Yb), lithium fluoride (LiF), platinum (Pt), palladium (Pd), molybdenum (Mo), iridium (Ir), and tin (Sn). Further, the first electrode 31 may be made of, for instance, alloy of astatine (At) and astatine oxide (AtO₂) or other alloys. Furthermore, the first electrode 31 may be made of, but not limited to, conductive oxide, including tin oxide (SnO), zinc oxide (ZnO), indium tin oxide (ITO), and indium zinc oxide (IZO). Further, the first electrode 31 may be formed by stacking multiple layers made of the above materials. It is noted that examples of a compound material having a large work function include indium tin oxide (ITO) and indium zinc oxide (IZO).

As illustrated in FIG. 6, the organic EL layer 33 includes a hole injection layer 1, a hole transport layer 2, a light-emitting layer 3, an electron transport layer 4, and an electron injection layer 5 sequentially stacked on the first electrode 31.

The hole injection layer 1 is also called an anode buffer layer and has the function of bringing the energy levels of the first electrode 31 and organic EL layer 33 close to each other to improve the efficiency of hole injection from the first electrode 31 into the organic EL layer 33. Here, examples of the material of the hole injection layer 1 include a triazole derivative, an oxadiazole derivative, an imidazole derivative, a polyarylalkane derivative, a pyrazoline derivative, a phenylenediamine derivative, an oxazole derivative, a styrylanthracene derivative, a fluorenone derivative, a hydrazone derivative, and a stilbene derivative.

The hole transport layer 2 has the function of improving the efficiency of hole transport from the first electrode 31 to the organic EL layer 33. Here, examples of the material of the hole transport layer 2 include a porphyrin derivative, an aromatic tertiary amine compound, a styrylamine derivative, polyvinylcarbazole, poly-p-phenylenevinylene, polysilane, a triazole derivative, an oxadiazole derivative, an imidazole derivative, a polyarylalkane derivative, a pyrazoline derivative, a pyrazolone derivative, a phenylenediamine derivative, an arylamine derivative, an amine-substituted chalcone derivative, an oxazole derivative, a styrylanthracene derivative, a fluorenone derivative, a hydrazone derivative, a stilbene derivative, hydrogenated amorphous silicon, hydrogenated amorphous silicon carbide, zinc sulfide, and zinc selenide.

The light-emitting layer 3 is a region in which holes and electrons are respectively injected from the first electrode 31 and second electrode 34 applied with voltage, and in which the holes and electrons recombine together. Here, the light-emitting layer 3 is made of a material having high efficiency of light emission. Moreover, examples of the material of the light-emitting layer 3 include a metal oxinoid compound [8-hydroxyquinoline metal complex], a naphthalene derivative, an anthracene derivative, a diphenylethylene derivative, a vinyl acetone derivative, a triphenylamine derivative, a butadiene derivative, a coumarin derivative, a benzoxazole derivative, an oxadiazole derivative, an oxazole derivative, a benzimidazole derivative, a thiadiazole derivative, a benzothiazole derivative, a styryl derivative, a styrylamine derivative, a bisstyrylbenzene derivative, a trisstyrilbenzene derivative, a perylene derivative, a perynone derivative, an aminopyrene derivative, a pyridine derivative, a rhodamine derivative, an acridine derivative, phenoxazone, a quinacridone derivative, rubrene, poly-p-phenylenevinylene, and polysilane.

The electron transport layer 4 has the function of moving electrons to the light-emitting layer 3 efficiently. Here, examples of the material of the electron transport layer 4 include organic compounds, such as an oxadiazole derivative, a triazole derivative, a benzoquinone derivative, a naphthoquinone derivative, an anthraquinone derivative, a tetracyanoanthraquinodimethane derivative, a diphenoquinone derivative, a fluorenone derivative, a silole derivative, and a metal oxinoid compound.

The electron injection layer 5 has the function of bringing the energy levels of the second electrode 34 and organic EL layer 33 close to each other to improve the efficiency of electron injection from the second electrode 34 into the organic EL layer 33. This function can lower a voltage for driving the organic EL element 35. It is noted that the electron injection layer 5 is also called a cathode buffer layer. Here, examples of the material of the electron injection layer 5 include inorganic alkali compounds, such as lithium fluoride (LiF), magnesium fluoride (MgF₂), calcium fluoride (CaF₂), strontium fluoride (SrF₂), or barium fluoride (BaF₂), as well as aluminum oxide (Al₂O₃) and strontium oxide (SrO).

The second electrode 34 is shared among all the subpixels P so as to cover the individual organic EL layers 33 and the edge cover 32, as illustrated in FIG. 3. Further, the second electrode 34 has the function of injecting electrons into the organic EL layers 33. Further, the second electrode 34 is more desirably made of a material having a small work function, in order to improve the efficiency of electron injection into the organic EL layers 33. Here, examples of the material of the second electrode 34 include silver (Ag), aluminum (Al), vanadium (V), calcium (Ca), titanium (Ti), yttrium (Y), sodium (Na), manganese (Mn), indium (In), magnesium (Mg), lithium (Li), ytterbium (Yb), and lithium fluoride (LiF). Further, the second electrode 34 may be made of, for instance, alloy of magnesium (Mg) and copper (Cu), alloy of magnesium (Mg) and silver (Ag), alloy of sodium (Na) and potassium (K), alloy of astatine (At) and astatine oxide (AtO₂), alloy of lithium (Li) and aluminum (Al), alloy of lithium (Li), calcium (Ca) and aluminum (Al), or alloy of lithium fluoride (LiF), calcium (Ca) and aluminum (Al). Further, the second electrode 34 may be composed of a conductive oxide, such as tin oxide (SnO), zinc oxide (ZnO), indium tin oxide (ITO), or indium zinc oxide (IZO). Further, the second electrode 34 may be formed by stacking multiple layers made of the above materials. It is noted that examples of a material having a small work function include magnesium (Mg), lithium (Li), lithium fluoride (LiF), magnesium (Mg)-copper (Cu), magnesium (Mg)-silver (Ag), sodium (Na)-potassium (K), lithium (Li)-aluminum (Al), lithium (Li)-calcium (Ca)-aluminum (Al), and lithium fluoride (LiF)-calcium (Ca)-aluminum (Al).

The edge cover 32 is composed of, but not limited to, an organic resin material, such as polyimide resin or acrylic resin, or a polysiloxane SOG material.

As illustrated in FIG. 3, the sealing film 45 is provided so as to cover the second electrode 34 and includes a first inorganic sealing film 41, an organic sealing film 42, and a second inorganic sealing film 43 stacked sequentially on the second electrode 34, and the sealing film 45 has the function of protecting the organic EL layers 33 of the organic EL elements 35 from moisture, oxygen, and other things.

The first inorganic sealing film 41 and the second inorganic sealing film 43 are composed of an inorganic insulating film, such as a silicon nitride film, a silicon oxide film, or a silicon oxide nitride film.

The organic sealing film 42 is composed of an organic resin material, such as acrylic resin, epoxy resin, silicone resin, polyurea resin, parylene resin, polyimide resin, or polyamide resin.

In each subpixel P of the organic EL display device 50 having the foregoing configuration, the emission control line 14e is firstly selected and deactivated, thus rendering the organic EL element 35 non-luminous. In this non-luminous state, the gate line 14g(n−1) at the anterior stage is selected, and a gate signal is input to the initialization TFT 9a via the gate line 14g(n−1), thus turning on the initialization TFT 9a, thus applying the high power-supply voltage ELVDD of the power supply line 20g to the capacitor 9h, and turning on the driving TFT 9d. Accordingly, the electric charge within the capacitor 9h is discharged to thus initialize the voltage applied to the gate electrode of the driving TFT 9d. Next, the gate line 14g(n) at the target stage is selected and activated, thus turning on the compensation TFT 9b and the write TFT 9c, thus writing a predetermined voltage corresponding to a source signal transmitted via the corresponding source line 20f, into the capacitor 9h via the driving TFT 9d being in diode connection, and turning on the anode discharge TFT 9g, thus applying an initialization signal to the first electrode 31 of the organic EL element 35 via the second initialization power-supply line 18i to thus reset the electric charge accumulated in the first electrode 31. Then, the emission control line 14e is selected, thus turning on the power supply TFT 9e and the emission control TFT 9f, thus supplying, from the power supply line 20g to the organic EL element 35, a driving current corresponding to the voltage applied to the gate electrode of the driving TFT 9d. In this way, the organic EL element 35 in each subpixel P emits light at a luminance level corresponding to the driving current, so that the organic EL display device 50 displays an image.

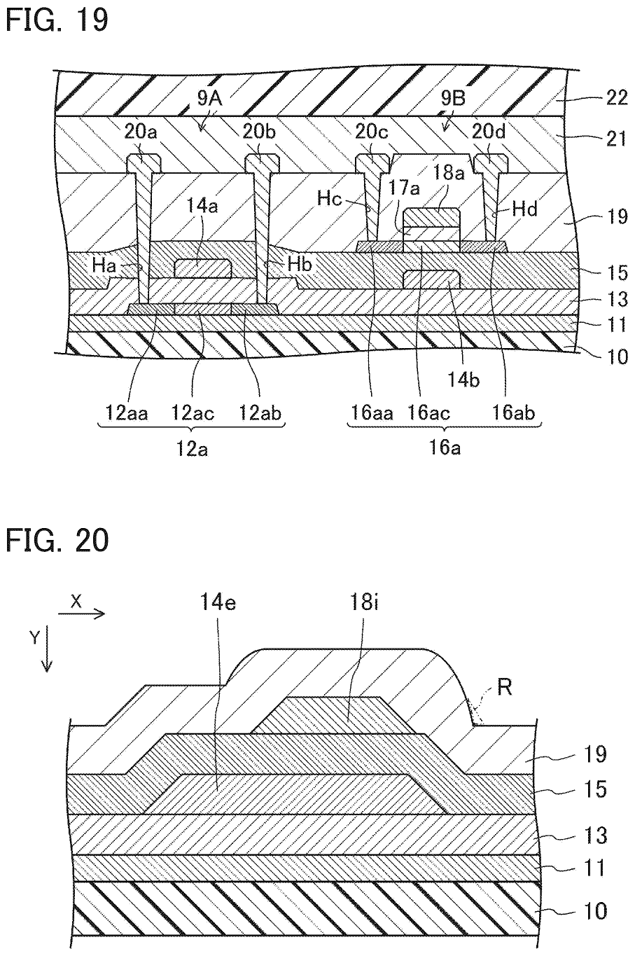

Next, a method for manufacturing the organic EL display device 50 according to this embodiment will be described. It is noted that the method for manufacturing the organic EL display device 50 includes a step of forming a TFT layer, a step of forming an organic EL element layer, and a step of forming a sealing film. Here, FIG. 7, FIG. 8, FIG. 9, FIG. 10, FIG. 11, FIG. 12, FIG. 13, FIG. 14, FIG. 15, FIG. 16, FIG. 17, FIG. 18, and FIG. 19 are respectively a first sectional view, a second sectional view, a third sectional view, a fourth sectional view, a fifth sectional view, a sixth sectional view, a seventh sectional view, an eighth sectional view, a ninth sectional view, a tenth sectional view, an eleventh sectional view, a twelfth sectional view, and a thirteenth sectional view that sequentially illustrate process steps (the step of forming the TFT layer) for manufacturing the organic EL display device 50. In addition, FIG. 20 illustrates a process step (the step of forming the TFT layer) for manufacturing the organic EL display device 50 and is a sectional view taken along line XX-XX in FIG. 2 after a step of patterning the third metal film 20.

### Step of Forming TFT Layer

The first process step is forming the base coat film 11 by forming a silicon nitride film (about 50 nm thick) and a silicon oxide film (about 250 nm thick) sequentially onto the resin substrate 10 formed on a glass substrate, through plasma chemical vapor deposition (CVD) for instance.

The next is forming an amorphous silicon film (about 50 nm thick) onto the substrate surface with the base coat film 11 formed thereon, through plasma CVD for instance, and crystallizing the amorphous silicon film through laser annealing or other methods, to thus form the first semiconductor film 12 made of polysilicon as illustrated in FIG. 7. The next is patterning the first semiconductor film 12 to form the first semiconductor layer 12a as illustrated in FIG. 8.

The next is forming a silicon oxide film (about 100 nm thick) onto the substrate surface with the first semiconductor layer 12a formed thereon, through plasma CVD for instance, to thus form the first gate insulating film 13, followed by forming a molybdenum film (about 200 nm thick) and other things through, for instance, sputtering to thus form the first metal film 14 as illustrated in FIG. 9.

The next is patterning the first metal film 14 to form the first gate electrode 14a, the third gate electrode 14b, and other things as illustrated in FIG. 10.

The next is doping of impurity ions, such as phosphorus ions, by using the first gate electrode 14a as a mask, to thus form the first conductor region 12aa, second conductor region 12ab, and first channel region 12a in the first semiconductor layer 12a.

The next is forming a silicon nitride film (about 150 nm thick) and a silicon oxide film (about 100 nm thick) sequentially onto the substrate surface doped with the ion impurities through plasma CVD for instance, to thus form the first interlayer insulating film 15, followed by forming an oxide semiconductor film (about 30 nm thick) of InGaZnO₄ or other oxides through, for instance, sputtering to thus form the second semiconductor film 16 as illustrated in FIG. 12.

The next is patterning the second semiconductor film 16 to form the second semiconductor layer 16a as illustrated in FIG. 13.

The next is forming a silicon oxide film (about 100 nm thick) onto the substrate surface with the second semiconductor layer 16a formed thereon, through plasma CVD for instance, to thus form a second-gate-insulating-film formation film 17, followed by forming a molybdenum film (about 200 nm thick) and other things through, for instance, sputtering to thus form the second metal film 18 as illustrated in FIG. 14.

The next is patterning the second metal film 18 and the second-gate-insulating-film formation film 17 to thus form the second gate insulating film 17a, the second gate electrode 18a, and other things as illustrated in FIG. 15.

The next is forming a silicon oxide film (about 300 nm thick) and a silicon nitride film (about 150 nm thick) sequentially onto the substrate surface with the second gate electrode 18a and other things formed thereon, through plasma CVD for instance, to thus form the second interlayer insulating film 19 as illustrated in FIG. 16. It is noted that part of the second semiconductor layer 16a is turned into a conductor through heating after the formation of the second interlayer insulating film 19, thus forming the third conductor region 16aa, fourth conductor region 16ab, and second channel region 16ac in the second semiconductor layer 16a.

The next is patterning the first gate insulating film 13, the first interlayer insulating film 15, and the second interlayer insulating film 19 onto the substrate surface with the second interlayer insulating film 19 formed thereon, to thus form the first contact hole Ha, the second contact hole Hb, the third contact hole Hc, the fourth contact hole Hd, and other things.

The next is forming, as a lower metal film and a middle metal film, a titanium film (about 50 nm thick) and an aluminum film (about 400 nm thick) sequentially onto the substrate surface with the first contact hole Ha and other things formed therein, through sputtering for instance, followed by patterning the stack of the titanium film and aluminum film through dry etching to thus form the lower metal layer 6 and the middle metal layer 7 (a first patterning step).

The next is forming, as an upper metal film, a titanium film (about 100 nm thick) onto the substrate surface with the lower metal layer 6 and middle metal layer 7 formed thereon, through sputtering for instance, to thus form the third metal film 20 (with the stack of the lower metal layer 6 and middle metal layer 7 covered with the upper metal film) as illustrated in FIG. 17.

The next is patterning the upper metal film of the third metal film 20 through dry etching to thus form the upper metal layer 8, thus forming the first terminal electrode 20a, the second terminal electrode 20b, the third terminal electrode 20c, the fourth terminal electrode 20d, and other things (a second patterning step) as illustrated in FIG. 18. Here, the surface step height of the second interlayer insulating film 19 is large, as illustrated in FIG. 20, on the substrate surface after the patterning of the third metal film 20; however, occurrence of a residue R on the third metal film 20 is prevented because the stack of the titanium film, aluminum film, and titanium film undergoes dry etching twice separately. It is noted that the source line 20f and the power supply line 20g, for instance, (formed onto the second interlayer insulating film 19 simultaneously with the first terminal electrode 21a and other things), which are formed so as to extend adjacently to each other in the X-direction in FIG. 20, are prevented from a short circuit between them because occurrence of the residue R of the third metal film 20 is prevented.

The next is forming a silicon oxide film (about 250 nm thick) onto the substrate surface with the first terminal electrode 20a and other things formed thereon, through plasma CVD for instance, to form the protective insulating film 21, followed by applying an acrylic protective insulating film (about 2 m thick) through, for instance, spin coating or slit coating, followed by subjecting the applied film to pre-baking, exposure, development, and post-baking to thus form, as illustrated in FIG. 19, the flattening film 22 having a contact hole (not shown).

The final process step is removing the protective insulating film 21 exposed from the contact hole of the flattening film 22, so that the contact hole reaches the second terminal electrode of the emission control TFT 9f.

The TFT layer 30 can be formed through the foregoing process steps.

It is noted that although this embodiment has described, by way of example, a method of forming the upper metal layer 8 so as to cover the individual end faces of the lower metal layer 6 and middle metal layer 7, the upper metal layer 8 may be formed in such a manner that the individual end faces of the lower metal layer 6 and middle metal layer 7 are exposed.

Step of Forming Organic EL Element Layer The organic EL element layer 40 is formed by forming, through a well-known method, the first electrode 31, the edge cover 32, the organic EL layer 33 (the hole injection layer 1, the hole transport layer 2, the light-emitting layer 3, the electron transport layer 4, and the electron injection layer 5), and the second electrode 34 onto the flattening film 22 of the TFT layer 30 formed in the step of forming the TFT layer.

### Step of Forming Sealing Film

The first process step is forming an inorganic insulating film, such as a silicon nitride film, a silicon oxide film, or a silicon oxide nitride film, onto the substrate surface on which the organic EL element layer 40 formed in the step of forming the organic EL element layer is formed, through plasma CVD using a mask to thus form the first inorganic sealing film 41.

The next is forming a film of an organic resin material, such as acrylic resin, onto the substrate surface with the first inorganic sealing film 41 formed thereon, through ink-jet printing for instance, to thus form the organic sealing film 42.

The next is forming an inorganic insulating film, such as a silicon nitride film, a silicon oxide film, or a silicon oxide nitride film, onto the substrate with the organic sealing film 42 formed thereon, through plasma CVD using a mask, to thus form the second inorganic sealing film 43, thereby forming the sealing film 45.

The final process step is attaching a protective sheet (not shown) to the substrate surface with the sealing film 45 formed thereon, followed by laser light irradiation from near the glass substrate of the resin substrate 10 to thus remove the glass substrate from the lower surface of the resin substrate 10, followed by attaching a protective sheet (not shown) to the lower surface of the resin substrate 10 with the glass substrate removed therefrom.

The organic EL display device 50 according to this embodiment can be manufactured through the foregoing process steps.

As described above, in the organic EL display device 50 and the method for manufacturing the same according to this embodiment, each of the terminal electrodes 20x, that is, each of the first terminal electrodes 20a and second terminal electrodes 20b of the first TFTs 9A, and the third terminal electrodes 20c and fourth terminal electrodes 20d of the second TFTs 9B includes the lower metal layer 6, the middle metal layer 7, and the upper metal layer 8 stacked sequentially. Moreover, at the end of each terminal electrode 20x, the end face of the lower metal layer 6 and the end face of the middle metal layer 7 are flush with each other, and the upper metal layer 8 is provided so as to cover these flush end faces. To achieve this structure of the end of the terminal electrode 20x, the first patterning step includes forming a lower metal film that is to be the lower metal layer 6, and a middle metal film that is to be the middle metal layer 7 sequentially onto the second interlayer insulating film 19, followed by patterning these lower metal film and middle metal film through dry etching to thus form the lower metal layer 6 and the middle metal layer 7 whose end faces are flush with each other. The subsequent second patterning step includes forming an upper metal film that is to be the upper metal layer 8, so as to cover the lower metal layer 6 and the middle metal layer 7, followed by patterning this upper metal film through dry etching to thus form the upper metal layer 8 so as to cover the flush end faces of the lower metal layer 6 and middle metal layer 7. Such a formation method, which includes patterning the lower metal film, the middle metal film, and the upper metal film through two-time dry etching, prevents the residue R of a metal film that possibly occurs when the lower metal film, the middle metal film, and the upper metal film undergo patterning through one-time dry etching. Accordingly, the first gate electrode 14a, the second gate electrode 18a, and the third gate electrode 14b are formed in a lower layer, thereby preventing occurrence of the residue R of the third metal film 20 on the second interlayer insulating film 19, which has a large surface step height; consequently, a short circuit can be prevented between the terminal electrodes 20x adjacent to each other (e.g., between the first terminal electrode 20a and the second terminal electrode 20b, and between the third terminal electrode 20c and the fourth terminal electrode 20d). Furthermore, at the end of each terminal electrode 20x, the end face of the lower metal layer 6 and the end face of the middle metal layer 7 are flush with each other, and the upper metal layer 8 is provided so as to cover these flush end faces, so that the middle metal layer 7 can be prevented from oxidation and corrosion; in particular, the second TFTs 9B composed of an oxide semiconductor can be prevented from property degradation.

Further, in the organic EL display device 50 and the method for manufacturing the same according to this embodiment, the source lines 20f and the power supply lines 20g, which are made of the same material and formed in the same layer as the first terminal electrode 20a, second terminal electrode 20b, third terminal electrode 20c and fourth terminal electrode 20d, each include the lower metal layer 6, the middle metal layer 7, and the upper metal layer 8 stacked sequentially, like each terminal electrode 20x. Moreover, at the ends on both sides of the source line 20f and power supply line 20g, the end face of the lower metal layer 6 and the end face of the middle metal layer 7 are flush with each other, and the upper metal layer 8 is provided so as to cover these flush end faces. Thus, like each terminal electrode 20x, occurrence of the residue R of the third metal film 20 is prevented on the second interlayer insulating film 19, which has a large surface step height; consequently, a short circuit can be prevented between the source line 20f and the power supply line 20g adjacent to each other. Furthermore, at the ends on both sides of the source line 20f and power supply line 20g, the end face of the lower metal layer 6 and the end face of the middle metal layer 7 are flush with each other, and the upper metal layer 8 is provided so as to cover these flush end faces, so that the middle metal layer 7 can be prevented from oxidation and corrosion; in particular, the second TFTs 9B composed of an oxide semiconductor can be prevented from property degradation.

Further, in the organic EL display device 50 and the method for manufacturing the same according to this embodiment, the second TFTs 9B are each configured such that the third gate electrode 14b is provided closer to the resin substrate 10 than the second semiconductor layer 16a so as to overlap the second channel region 16ac; this configuration prevents the impurity ions contained in the resin substrate 10 from being diffused into the second channel region 16ac and prevents light entrance into the second channel region 16ac, so that the second TFTs 9B can be prevented from property degradation.

Further, in the organic EL display device 50 and the method for manufacturing the same according to this embodiment, the second TFTs 9B, each of which has a double-gate structure including the second gate electrode 18a and third gate electrode 14b, can improve its driving capability.

Further, in the organic EL display device 50 and the method for manufacturing the same according to this embodiment, the base coat film 11 composed of an inorganic insulating film is provided between the resin substrate 10 and the first semiconductor layer 12a, so that the films, such as the first semiconductor layer 12a, can be prevented from removal.

### Other Embodiments

Although the foregoing embodiment has described, by way of example, an organic EL layer of five-ply stacked structure composed of a hole injection layer, a hole transport layer, a light-emitting layer, an electron transport layer, and an electron injection layer, the organic EL layer may be of, for instance, three-ply stacked structure composed of a hole injection-and-transport layer, a light-emitting layer, and an electron transport-and-injection layer.

Further, although the foregoing embodiment has described, by way of example, an organic EL display device having a first electrode as an anode, and a second electrode as a cathode, the disclosure is also applicable to an organic EL display device with the stacked structure of its organic EL layer being inverted: a first electrode as a cathode, and a second electrode as an anode.

Further, although the foregoing embodiment has described an organic EL display device as a display device by way of example, the disclosure is applicable to a display device provided with a plurality of light-emitting elements that are driven by current; for instance, the disclosure is applicable to a display device provided with quantum-dot light-emitting diodes (QLEDs), which are light-emitting elements having a quantum-dot-containing layer.

### INDUSTRIAL APPLICABILITY

As described above, the disclosure is useful for flexible display devices.

1. A display device comprising:
a base substrate; and
a thin-film transistor layer provided on the base substrate, and in which a first semiconductor film composed of polysilicon, a first inorganic insulating film, a first metal film, a second inorganic insulating film, a second semiconductor film composed an oxide semiconductor, a third inorganic insulating film as well as a second metal film, and a fourth inorganic insulating film as well as a third metal film are stacked sequentially,
the thin-film transistor layer including a first thin-film transistor and a second thin-film transistor provided for each of subpixels constituting a display region, wherein the first thin-film transistor has a first semiconductor layer composed of the first semiconductor film, and the second thin-film transistor has a second semiconductor layer composed of the second semiconductor film,
the first thin-film transistor including
the first semiconductor layer having a first conductor region and a second conductor region defined so as to be spaced from each other, and having a first channel region defined between the first conductor region and the second conductor region,
a first gate electrode composed of the first metal film, and provided on the first semiconductor layer with the first inorganic insulating film interposed between the first gate electrode and the first semiconductor layer, and
a first terminal electrode and a second terminal electrode composed the third metal film, provided so as to be spaced from each other, and electrically connected to the first conductor region and the second conductor region, respectively,
the second thin-film transistor including
the second semiconductor layer having a third conductor region and a fourth conductor region defined so as to be spaced from each other, and having a second channel region defined between the third conductor region and the fourth conductor region,
a second gate electrode composed of the second metal film, and provided on the second semiconductor layer with the third inorganic insulating film interposed between the second gate electrode and the second semiconductor layer, and
a third terminal electrode and a fourth terminal electrode composed of the third metal film, provided so as to be spaced from each other, and electrically connected to the third conductor region and the fourth conductor region, respectively,
wherein each of the first terminal electrode, the second terminal electrode, the third terminal electrode, and the fourth terminal electrode includes a lower metal layer, a middle metal layer, and an upper metal layer stacked sequentially,
the middle metal layer has a lower electrical resistance and a lower melting point than the lower metal layer and the upper metal layer, and
at an end of each of the first terminal electrode, the second terminal electrode, the third terminal electrode, and the fourth terminal electrode, an end face of the lower metal layer and an end face of the middle metal layer are flush with each other, and the upper metal layer is provided so as to cover the end faces flush with each other.

2. The display device according to claim 1, wherein
the second thin-film transistor includes a third gate electrode composed of the first metal film, and provided closer to the base substrate than the second semiconductor layer with the second inorganic insulating film interposed between the third gate electrode and the second semiconductor layer.

3. The display device according to claim 1, wherein
the third inorganic insulating film is provided so as to overlap the second gate electrode.

4. The display device according to claim 1, wherein
the lower metal layer and the upper metal layer are composed of either a titanium film or a molybdenum film, and
the middle metal layer is composed of an aluminum film.

5. The display device according to claim 1, wherein
the thin-film transistor layer includes a plurality of source lines provided so as to extend in parallel with each other and composed of the third metal film, and a plurality of power supply lines each provided between the plurality of source lines, provided so as to extend in parallel with each other and composed of the third metal film,
each of the plurality of source lines and each of the plurality of power supply lines include the lower metal layer, the middle metal layer, and the upper metal layer, and
at ends on both sides of each of the plurality of source lines and each of the plurality of power supply lines, an end face of the lower metal layer and an end face of the middle metal layer are flush with each other, and the upper metal layer is provided so as to cover the end faces flush with each other.

6. The display device according to claim 1, wherein
the base substrate is composed of an organic resin material.

7. The display device according to claim 6, comprising a base coat film provided on the base substrate,
wherein the first semiconductor layer is provided on the base coat film.

8. The display device according to claim 1, comprising:
a light-emitting element layer provided on the thin-film transistor layer, and in which a plurality of light-emitting elements are arranged; and
a sealing film provided on the light-emitting element layer.

9. The display device according to claim 8, wherein
each of the plurality of light-emitting elements is an organic electroluminescence element.

10. A method for manufacturing the display device according to claim 1, comprising a step of patterning the third metal film,
wherein the step includes
a first patterning step of forming a lower metal film that is to be the lower metal layer, and a middle metal film that is to be the middle metal layer sequentially onto the fourth inorganic insulating film, followed by patterning the lower metal film and the middle metal film through dry etching to form the lower metal layer and the middle metal layer, and
a second patterning step of forming an upper metal film that is to be the upper metal layer, so as to cover the lower metal layer and the middle metal layer formed in the first patterning step, followed by patterning the upper metal film through dry etching to form the upper metal layer.
